(19) United States
(12) Patent Application Publication
(10) Pub. No.: US 2013/0328405 A1
(43) Pub. Date: Dec. 12, 2013

(54) GROUND TEST CIRCUIT

(71) Applicants: YUN BAI, Shenzhen (CN); PENG CHEN, Shenzhen (CN); SONG-LIN TONG, Shenzhen (CN)

(72) Inventors: YUN BAI, Shenzhen (CN); PENG CHEN, Shenzhen (CN); SONG-LIN TONG, Shenzhen (CN)

(21) Appl. No.: 13/680,129

(22) Filed: Nov. 19, 2012

(30) Foreign Application Priority Data
Jun. 6, 2012 (CN) 201210184077.X

(51) Int. Cl. G01R 31/40; H02J 4/00

(52) U.S. Cl. CPC G01R 31/40; H02J 4/00
USPC 307/80; 324/764.01

(57) ABSTRACT

A ground test circuit for a power supply unit includes a sampling circuit, a converting circuit, a processing circuit, and a switch circuit. The sampling circuit detects a voltage difference between a first ground terminal and a second ground terminal. The converting circuit converts the voltage difference to a digital value. The processing circuit compares the digital value to a predetermined value. As long as the digital value is smaller than the predetermined value, the switch circuit allows an external power source to be connected to the power supply unit. Thereby, the ground test circuit controls the connection between the external power source and the power supply unit according to the result of comparison of values done by the processing circuit.

### BACKGROUND

1. Technical Field

The present disclosure relates to a ground test circuit, and particularly to a ground test circuit for a power supply unit.

2. Description of Related Art

A power test for a computer motherboard is very complex, so a testing equipment which works automatically is conventionally used to perform this power test. The automatic testing equipment includes a direct current (DC) power source, a DC load, an oscilloscope, a power supply unit (PSU), a digital meter and other functions, and these devices can be connected through a general purpose input/output (GPIO) control port and grounded through the PSU. However, a waveform of the test result will be incorrect if these devices are not properly grounded through the PSU before testing. In addition, electrostatic discharge may occur due to a ground fault.

Therefore, there is need for improvement in the art.

### BRIEF DESCRIPTION OF THE DRAWINGS

Many aspects of the present disclosure can be better understood with reference to the following drawing(s). The components in the drawing(s) are not necessarily drawn to scale, the emphasis instead being placed upon clearly illustrating the principles of the present disclosure. Moreover, in the drawing(s), like reference numerals designate corresponding parts throughout the several views.

FIG. 1 is a block diagram of an embodiment of a ground test circuit of the present disclosure.

FIG. 2 is a circuit diagram of an embodiment of a sampling circuit of a ground test circuit of the present disclosure.

FIG. 3 is a circuit diagram of an embodiment of a control circuit of a ground test circuit of the present disclosure.

FIG. 4 is a circuit diagram of an embodiment of a switch circuit of a ground test circuit of the present disclosure.

### DETAILED DESCRIPTION

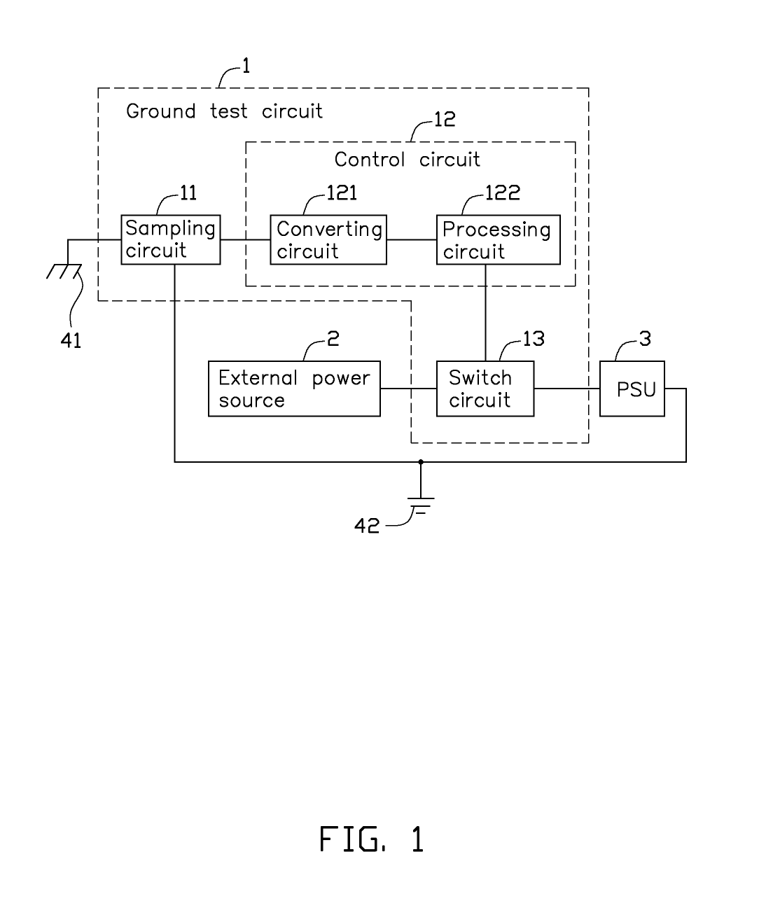

As shown in FIG. 1, a ground test circuit 1 in an embodiment includes a sampling circuit 11, a control circuit 12, and a switch circuit 13. In the embodiment, the ground test circuit 1 is connected to an external power source 2 and to a power supply unit (PSU) 3. In addition, the control circuit 12 can include a converting circuit 121 and a processing circuit 122. In the embodiment, the ground test circuit 1 is installed in automatic testing equipment.

The sampling circuit 11 is connected to a first ground terminal 41 and a second ground terminal 42 to detect a voltage difference between the first ground terminal 41 and the second ground terminal 42. The first ground terminal 41 is grounded through an actual ground, and the second ground terminal 42 is grounded through a virtual ground. A negative output terminal of the PSU 3 is connected to the sampling circuit 11 and grounded as a system ground terminal of the PSU 3 through the virtual ground. Therefore, the voltage different between the first ground terminal 41 and the second ground terminal 42 is equal to a voltage different between the first ground terminal 41 and the negative output terminal of the PSU 3. The sampling circuit 11 is connected to the converting circuit 121. The converting circuit 121 converts the voltage difference between the first and second ground terminals 41 and 42 to a difference value and transmits the difference value to the processing circuit 122. The processing circuit 122 compares the difference value to a predetermined value. In the embodiment, the converting circuit 121 is an analog to digital converter, and the difference value is a digital value. In the embodiment, the processing circuit 122 determines whether the difference value is smaller or larger than the predetermined value. In other embodiments, the ground test circuit 1 can be a voltage difference test circuit, and the sampling circuit 11 of the voltage difference test circuit is connected to a first voltage terminal and a second voltage terminal to detect any voltage difference between the first voltage terminal and the second voltage terminal.

The switch circuit 13 is connected to the processing circuit 122. When the difference value is smaller than the predetermined value, the processing circuit 122 determines that the negative output terminal of the PSU 3 is properly grounded. For example, assume the negative output terminal of the PSU 3 has been grounded through an actual ground. At this time, the processing circuit 122 controls the switch circuit 13 to allow the external power source 2 to be connected to the PSU 3. When the difference value is at least equal to the predetermined value, the processing circuit 122 determines that the negative output terminal of the PSU 3 is not properly grounded and controls the switch circuit 13 to disconnect the PSU 3 from the external power source 2. In other words, the switch circuit 13 can connect the PSU 3 to the external power source 2 according to the result of the comparison between the difference value and the predetermined value.

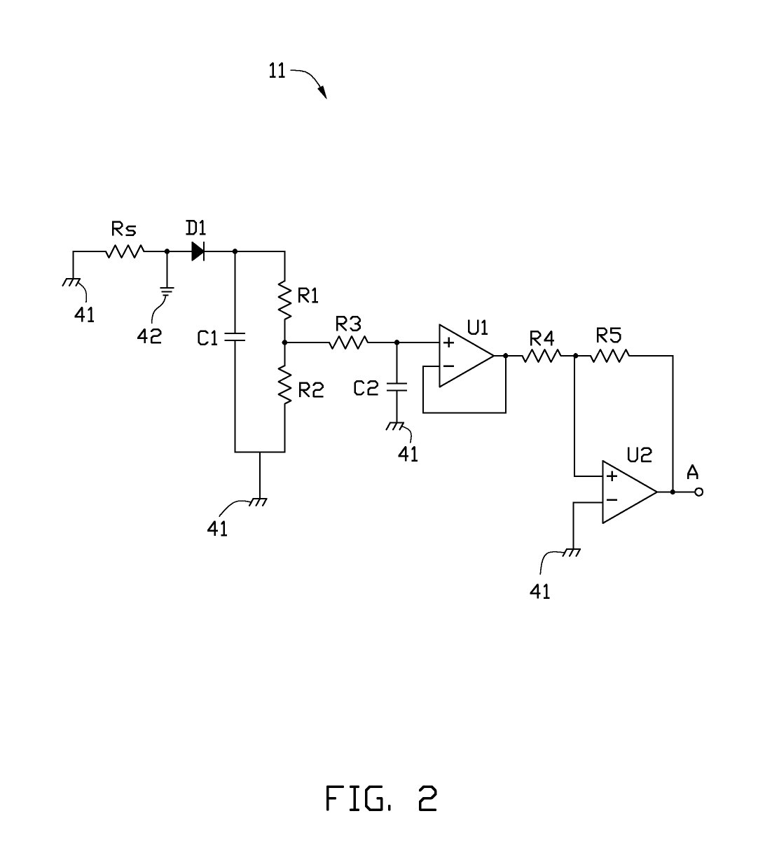

As shown in FIG. 2, the sampling circuit 11 includes a sensing resistor Rs, a first diode D1, first and second amplifier units U1 and U2, first to fifth resistors R1-R5, and first and second capacitors C1 and C2. A first terminal of the sensing resistor Rs is connected to the first ground terminal 41, and a second terminal of the sensing resistor Rs is connected to the second ground terminal 42. Therefore, the voltage difference between the first and second ground terminals 41 and 42 is a terminal voltage between the first and second terminals of the sensing resistor Rs. The second terminal of the sensing resistor Rs is also connected to an anode of the first diode D1. A cathode of the first diode D1 is connected to the first ground terminal 41 through the first capacitor C1 and through the first and second resistors R1 and R2. A node between the first and second resistors R1 and R2 is connected to a positive input terminal of the first amplifier unit U1 through the third resistor R3. The positive input terminal of the first amplifier unit U1 is also connected to the first ground terminal 41 through the second capacitor C2. A negative input terminal of the first amplifier unit U1 is connected to an output terminal of the first amplifier unit U1. The output terminal of the first amplifier unit U1 is connected to a positive input terminal of the second amplifier unit U2 through the fourth resistor R4. A negative input terminal of the second amplifier unit U2 is grounded through the first ground terminal 41. An output terminal of the second amplifier unit U2 is connected to the positive input terminal of the second amplifier unit U2 through the fifth resistor R5 and connected to the converting circuit 121.

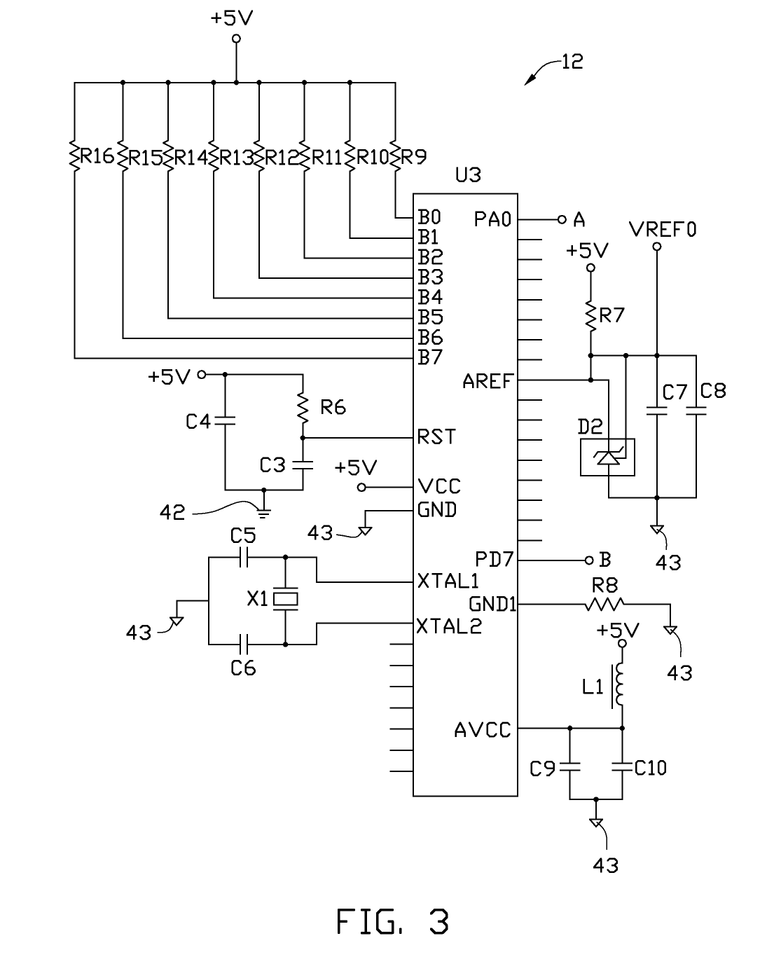

As shown in FIG. 3, the control circuit 12 in the embodiment includes a microcontroller U3, sixth to sixteenth resistors R6-R16, third to tenth capacitors C3-C10, an oscillating unit X1, a regulator unit D2 and an inductor L1. The microcontroller U3 further includes first to eighth bus pins B0-B7, a reset pin RST, first and second power pins VCC and AVCC, first and second ground pins GND and GND1, first and second clock pins XTAL1 and XTAL2, an input pin PA0, an output pin PD7, and a reference voltage pin AREF.

Each of the first to eighth bus pins B0-B7 is connected to a first power source through one of the ninth to sixteenth resistors R9-R16. For example, the first bus pin B0 is connected through the ninth resistor R9, and the second bus pin B1 is connected through the tenth resistor R10. The reset pin RST is connected to the first power source through the sixth resistor R6. In addition, the reset pin RST is also connected to the first power source through the third and fourth capacitors C3 and C4. A node between the third and fourth capacitors is connected to the second ground terminal 42. The first power pin VCC is connected to the first power source, and the first ground pin GND is grounded through a third ground terminal 43. In the embodiment, the third ground terminal 43 is a signal ground terminal and can function as the system ground terminal through the virtual ground. The first clock pin XTAL1 is connected to a first terminal of the oscillating unit X1 and connected to the third ground terminal 43 through the fifth capacitor C5, and the second clock pin XTAL2 is connected to a second terminal of the oscillating unit X1 and connected to the third ground terminal 43 through the sixth capacitor C6. The input pin PA0 is connected to the sampling circuit 11, and the output pin PD7 is connected to the switch circuit 13.

The reference voltage pin AREF is connected to the first power source through the seventh resistor R7 and connected to first and second terminals of the regulator unit D2. In addition, the reference voltage pin AREF is connected to the third ground terminal 43 through the seventh capacitor C7 and through the eighth capacitor C8. A reference power source is connected to the reference voltage pin AREF. A third terminal of the regulator unit D2 is connected to the third ground terminal 43. The second ground pin GND1 is connected to the third ground terminal 43 through the eighth resistor R8. The second power pin AVCC is connected to the first power source through the inductor L1. In addition, the second power pin AVCC is connected to the third ground terminal 43 through the ninth capacitor C9 and through the tenth capacitor C10. In the embodiment, the other pins of the microcontroller U3 are unconnected. In the embodiment, the regulator unit D2 is a three-terminal adjustable regulator, wherein the first terminal of the regulator unit D2 is a cathode, the second terminal of the regulator unit D2 is a reference, and the third terminal of the regulator unit D2 is an anode.

The microcontroller U3 converts the voltage difference received by the input pin PA0 to the difference value and compares the difference value to a predetermined value stored in the microcontroller U3. When the difference value is smaller than the predetermined value, the output pins PD7 transmits a high level signal. When the difference value is at least equal to the predetermined value, the output pins PD7 transmits a low level signal.

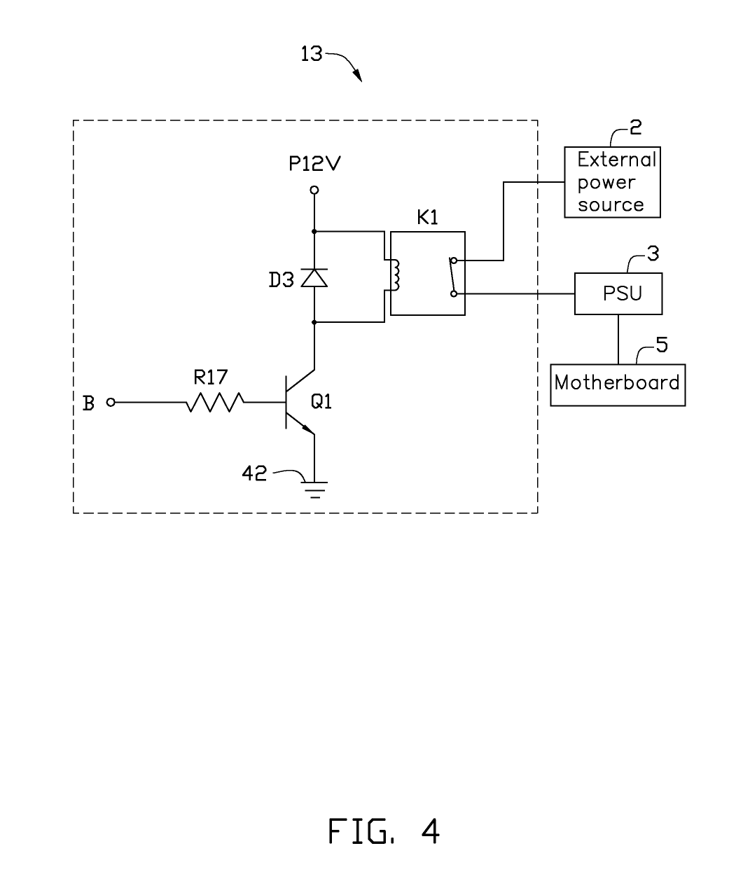

As shown in FIG. 4, the switch circuit 13 includes first and second switch elements Q1 and K1, a seventeenth resistor R17 and a second diode D3. The first switch element Q1 has first to third terminals, and the second switch element K1 has first to fourth terminals. In the embodiment, the first switch element Q1 is a bipolar junction transistor (BJT), wherein the first terminal of the BJT is a base, the second terminal of the BJT is a collector, and the third terminal of the BJT is an emitter. In addition, the second switch element K1 is a relay having a coil and a switch, wherein the first and second terminals of the relay are two terminals of the coil, and the third and fourth terminals of the relay are two terminals of the switch.

The base of the first switch element Q1 is connected to the processing circuit 122 through the seventeenth resistor R17. In the embodiment, the base of the first switch element Q1 is connected to the output pin PD7 of the microcontroller U3 through the seventeenth resistor R17. The collector of the first switch element Q1 is connected to an anode of the second diode D3. The emitter of the first switch element Q1 is grounded through the second ground terminal 42. A cathode of the second diode D3 is connected to a second power source. In addition, the anode of the second diode D3 is connected to one of the two terminals of the coil, and the cathode of the second diode D3 is connected to the other terminal of the coil. The external power source 2 is connected to one of the two terminals of the switch, and the PSU 3 is connected to the other terminal of the switch. The PSU 3 is further connected to a motherboard 5 to be tested.

In the embodiment, the base of the first switch element Q1 receives either a high level signal or a low level signal from the output pin PD7 of the microcontroller U3. A voltage difference between a high level potential of the high level signal and a ground potential of the second ground terminal 42 is larger than a threshold voltage of the first switch element Q1, and a voltage difference between a low level potential of the low level signal and the ground potential of the second ground terminal 42 is smaller than the threshold voltage of the first switch element Q1. Thus, the first switch element Q1 is turned on when the high level signal is received. The first switch element Q1 is turned off when the low level signal is received.

An operating principle of the embodiment of the present disclosure is described as follows.

The terminal voltage between the first and second terminals of the sensing resistor RS is detected by the sampling circuit 11 and transmitted to the control circuit 12 through the first and second amplifier units U1 and U2. The microcontroller U3 converts the voltage difference, i.e. the terminal voltage, to the difference value, and compares the difference value to the predetermined value. When the difference value is smaller the predetermined value, the microcontroller U3 determines that the negative output terminal of the PSU 3 is properly grounded. For example, assume the negative output terminal of the PSU 3 is grounded through an actual ground. Then, the output pin PD7 of the microcontroller U3 transmits a high level signal to the switch circuit 13. The first switch element Q1 receives the high level signal and turns on so that the second diode D3 is turned off. Therefore, current will flow through the coil of the second switch element K1 and the switch of the second switch element K1 will be closed. Accordingly, the external power source 2 is able to supply power to the PSU 3. In the embodiment, the predetermined value corresponds to a predetermined voltage, and the predetermined voltage is 5V. Thus, the microcontroller U3 determines that the negative output terminal of the PSU 3 is properly grounded when the voltage difference is smaller than 5V.

When the difference value is at least equal to the predetermined value, the microcontroller U3 determines that the negative output terminal of the PSU 3 is not properly grounded. Then, the output pin PD7 of the microcontroller U3 transmits a low level signal to the switch circuit 13. The first switch element Q1 receives the low level signal and turns off the first switch element Q1. Therefore, no current flows through the coil of the second switch element K1 and the switch of the second switch element K1 will be open. Accordingly, the external power source 2 is not permitted to supply power to the PSU 3. In the embodiment, the microcontroller U3 determines that the negative output terminal of the PSU 3 is not properly grounded when the voltage difference is 5V or more.

The circuit of the above ground test circuit 1 uses a sensing resistor Rs to detect a terminal voltage between two terminals of the sensing resistor Rs for detecting a voltage difference between an actual ground and a system ground of the PSU 3. In addition, the ground test circuit 1 further converts the voltage difference to a digital value and compares the digital value to a predetermined value. If the digital value is smaller than the predetermined value, the PSU 3 is considered to be properly grounded. Moreover, the ground test circuit 1 uses a relay to control the connection between the external power source 2 and the PSU 3 according to the result of the comparison done by the processing circuit 122. The external power source 2 is able to supply power to the PSU 3 when the PSU 3 is considered to be properly grounded. Thus, a ground fault can be prevented and the waveform in the test result will be more reliable. In addition, the risk of electrostatic discharge to a user is also reduced by the ground test circuit 1.

While the disclosure has been described by way of example and in terms of various embodiments, it is to be understood that the disclosure is not limited thereto. On the contrary, it is intended to cover various modifications and similar arrangements as would be apparent to those skilled in the art. Therefore, the range of the appended claims should be accorded the broadest interpretation so as to encompass all such modifications and similar arrangements.

What is claimed is:

1. A ground test circuit for a power supply unit comprising:
a sampling circuit connecting to a first ground terminal and a second ground terminal and configured to detect a voltage difference between the first ground terminal and the second ground terminal;
a control circuit configured to convert the voltage difference to a difference value and to compare the difference value with a predetermined value; and
a switch circuit configured to switch a connection between the power supply unit and an external power source according to a result of the comparison.

2. The ground test circuit of claim 1, wherein the sampling circuit comprises a sensing resistor, wherein a first terminal of the sensing resistor is connected to the first ground terminal and a second terminal of the sensing resistor is connected to the second ground terminal.

3. The ground test circuit of claim 2, wherein the first ground terminal is grounded through an actual ground, and the second ground terminal is grounded through a virtual ground.

4. The ground test circuit of claim 3, wherein a negative output terminal of the power supply unit is connected to the sampling circuit and grounded through the virtual ground.

5. The ground test circuit of claim 4, wherein the voltage difference between the first and second ground terminals is equal to a voltage difference between the actual ground and the negative output terminal of the power supply unit.

6. The ground test circuit of claim 2, wherein the voltage difference between the first and second ground terminals is a terminal voltage between the first and second terminals of the sensing resistor.

7. The ground test circuit of claim 2, wherein the sampling circuit further comprises a first diode, first and second amplifier units, first to fifth resistors, and first and second capacitors, wherein an anode of the first diode is connected to the second terminal of the sensing resistor, a cathode of the first diode is connected to the first ground terminal through the first capacitor and through the first and second resistors, a node between the first and second resistors is connected to a positive input terminal of the first amplifier unit through the third resistor, the positive input terminal of the first amplifier unit is connected to the first ground terminal through the second capacitor, a negative input terminal of the first amplifier unit is connected to an output terminal of the first amplifier unit, the output terminal of the first amplifier unit is connected to a positive input terminal of the second amplifier unit through the fourth resistor, a negative input terminal of the second amplifier unit is grounded through the first ground terminal, and an output terminal of the second amplifier unit is connected to the positive input terminal of the second amplifier unit through the fifth resistor and connected to the control circuit.

8. The ground test circuit of claim 1, wherein the control circuit comprises a microcontroller, sixth to eighth resistors, third to tenth capacitors, an oscillating unit, a regulator unit and an inductor, a reset pin of the microcontroller is connected to a first power source through the sixth resistor and through the third and fourth capacitors, a node between the third and fourth capacitors is connected to the second ground terminal, a first power pin of the microcontroller is connected to the first power source, a first ground pin of the microcontroller is grounded through a third ground terminal, a first clock pin of the microcontroller is connected to a first terminal of the oscillating unit and connected to the third ground terminal through the fifth capacitor, a second clock pin of the microcontroller is connected to a second terminal of the oscillating unit and connected to the third ground terminal through the sixth capacitor, an input pin of the microcontroller is connected to the sampling circuit, an output pin of the microcontroller is connected to the switch circuit, a reference voltage pin of the microcontroller is connected to the first power source through the seventh resistor, connected to first and second terminals of the regulator unit and connected to the third ground terminal through the seventh capacitor and through the eighth capacitor, a third terminal of the regulator unit is connected to the third ground terminal, the reference voltage pin is connected to a reference power source, a second ground pin of the microcontroller is connected to the third ground terminal through the eighth resistor, and a second power pin of the microcontroller is connected to the first power source through the inductor and connected to the third ground terminal through the ninth capacitor and through the tenth capacitor.

9. The ground test circuit of claim 1, wherein the control circuit controls the switch circuit to allow the external power source to be connected to the power supply unit when the difference value is smaller than the predetermined value, and to disconnect the power supply unit from the external power source when the difference value is at least equal to the predetermined value.

10. The ground test circuit of claim 1, wherein the switch circuit comprises first and second switch elements, a ninth resistor and a second diode, a first terminal of the first switch element is connected to the control circuit through the ninth resistor, a second terminal of the first switch element is connected to an anode of the second diode, a third terminal of the first switch element is grounded through the second ground terminal, a cathode of the second diode is connected to a second power source, the anode of the second diode is connected to a first terminal of the second switch element, the cathode of the second diode is connected to a second terminal of the second switch element, the external power source is connected to a third terminal of the second switch element, and the power supply unit is connected to a fourth terminal of the second switch element.

11. The ground test circuit of claim 10, wherein the first switch element is a bipolar junction transistor (BJT), the first terminal of the BJT is a base, the second terminal of the BJT is a collector, the third terminal of the BJT is an emitter, the second switch element is a relay having a coil and a switch, the first and second terminals of the relay are two terminals of the coil, and the third and fourth terminals of the relay are two terminals of the switch.

12. The ground test circuit of claim 1, wherein the control circuit comprising:
a converting circuit configured to receive the voltage difference and convert the voltage difference to the difference value; and
a processing circuit configured to compare the difference value with the predetermined value.

13. A voltage difference test circuit for a power supply unit comprising:
a sampling circuit connecting to a first voltage terminal and a second voltage terminal and configured to detect a voltage difference between the first voltage terminal and the second voltage terminal; and
a converting circuit configured to convert the voltage difference to a difference value; and
a processing circuit configured to compare the difference value with a predetermined value.

14. The voltage difference test circuit of claim 13, comprising:
a switch circuit configured to switch a connection between the power supply unit and an external power source according to a result of the comparison.

15. The voltage difference test circuit of claim 13, wherein the first voltage terminal is grounded through an actual ground, the second voltage terminal is grounded through a virtual ground, and the difference value is a digital value.
